(19) United States
(12) Patent Application Publication
(10) Pub. No.: US 2024/0204091 A1
(43) Pub. Date: Jun. 20, 2024

(54) LOW ALUMINUM CONCENTRATION ALUMINUM GALLIUM NITRIDE INTERLAYER FOR GROUP III-NITRIDE (III-N) DEVICES

(71) Applicant: Intel Corporation, Santa Clara, CA (US)

(72) Inventors: Heli Vora, Portland, OR (US); Marko Radosavljevic, Portland, OR (US); Pratik Koirala, Portland, OR (US); Han Wui Then, Portland, OR (US); Michael Beumer, Portland, OR (US); Ahmad Zubair, Hillsboro, OR (US); Samuel Bader, Hillsboro, OR (US)

(73) Assignee: Intel Corporation, Santa Clara, CA (US)

(21) Appl. No.: 18/084,438

(22) Filed: Dec. 19, 2022

(51) Int. Cl. H01L 29/778; H01L 21/285; H01L 21/306; H01L 29/20; H01L 29/47; H01L 29/66

(52) U.S. Cl. CPC H01L 29/7786; H01L 21/28581; H01L 21/30621; H01L 29/2003; H01L 29/475; H01L 29/66462

(57) ABSTRACT

Devices, transistor structures, systems, and techniques are described herein related to low aluminum concentration aluminum gallium nitride interlayers for group III-nitride enhancement mode transistors. The low aluminum concentration aluminum gallium nitride interlayer includes a lower aluminum concentration than a polarization layer of the transistor, such that the polarization layer induces a two-dimensional electron gas in a semiconductor layer of the transistor. The low aluminum concentration aluminum gallium nitride interlayer may be implemented as an etch stop layer, as a gate liner, or both.

### BACKGROUND

In the fields of wireless communication, power management, and others, components can be implemented using solid-state devices. For example, power management integrated circuits

(PMIC) and radio frequency integrated circuits (RFIC) are critical functional blocks in systems including system on a chip (SoC) implementations. Such systems may be found in mobile computing platforms such as smartphones, tablets, laptops, netbooks, and the like. Notably, the PMIC and RFIC are important factors for power efficiency and form factor that can be as or more important than logic and memory circuits.

In some implementations, III-N material based transistors, such as gallium nitride (GaN) based transistors may be used for high voltage and/or high frequency applications. For example, gallium nitride based devices may be advantageous because GaN has a wide band gap (˜3.4 eV) as compared to silicon (Si; ˜1.1 eV). The wide band gap may allow a GaN transistor to withstand a larger electric field (e.g., applied voltage, VDD) before suffering breakdown as compared to Si transistors of similar dimensions. Furthermore, GaN transistors may be scaled to even smaller dimensions while operating at the same Vcc. As such, there is an ongoing need for improved III-N material based transistors for wireless communication, power management, and other applications.

It is with respect to these and other considerations that the present improvements have been needed. Such improvements may become critical as the desire to improve computational efficiency become even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a cross-sectional side view of a device material stack for use in a high electron mobility transistor operating in enhancement mode;

FIG. 2 is a flow diagram illustrating methods for forming a group III-N high electron mobility transistor (HEMT) structure having a low aluminum concentration aluminum gallium nitride layer;

FIGS. 3A, 3B, 3C, 3D, 3E, 3F, 3G, 3H, and 3I are cross-sectional views of a HEMT structure having a low aluminum concentration aluminum gallium nitride layer between the gate and source and the gate and drain evolving as the methods of FIG. 2 are practiced;

FIGS. 4A and 4B are cross-sectional views of a HEMT structure having a low aluminum concentration aluminum gallium nitride layer gate liner and a low aluminum concentration aluminum gallium nitride layer between the gate and source and the gate and drain evolving as the methods of FIG. 2 are practiced;

FIGS. 5A, 5B, 5C, and 5D are cross-sectional views of a HEMT structure having a low aluminum concentration aluminum gallium nitride layer gate liner as the methods of FIG. 2 are practiced;

FIG. 6 illustrates exemplary systems employing a HEMT with a low aluminum concentration aluminum gallium nitride interlayer; and

FIG. 7 is a functional block diagram of an electronic computing device, all in accordance with some embodiments.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. Herein, the term “predominantly” indicates not less than 50% of a particular material or component while the term “substantially pure” indicates not less than 99% of the particular material or component and the term “pure” indicates not less than 99.9% of the particular material or component. Unless otherwise indicated, such material percentages are based on atomic percentage. Herein the term concentration is used interchangeably with material percentage and also indicates atomic percentage unless otherwise indicated.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/-10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. As used herein, the terms “monolithic”, “monolithically integrated”, and similar terms indicate the components of the monolithic overall structure form an indivisible whole not reasonably capable of being separated.

Device structures, transistor structures, integrated circuit dies, apparatuses, systems, and techniques are described herein related to the deployment of a low aluminum concentration aluminum gallium nitride interlayer for improved group III-nitride (III-N) devices.

As discussed, there is a need for improved III-N material based devices such as transistors for implementation in a variety of contexts including high voltage and/or high frequency applications. For example, in such III-N material based devices, a substantially pure or pure gallium nitride (GaN) layer may be deployed as the channel semiconductor in a high electron mobility transistor (HEMT). In enhancement mode HEMT devices, a two-dimensional electron gas (2DEG) is induced in the GaN layer by an aluminum gallium nitride (AlₓGaₓ₋₁N) layer that is adjacent to the GaN channel layer. The induced 2DEG is adjacent to a channel region over a gate of the device and, when a threshold volage is applied to the gate, current flows from the source to the drain through the channel region.

In some embodiments, the AlₓGaₓ₋₁N layer, or polarization layer, is a high aluminum concentration layer to provide the induced 2DEG in the GaN layer. For example, a high aluminum concentration layer of about 40% Al (i.e., x≈0.4) may provide the necessary polarization difference between the AlₓGaₓ₋₁N polarization layer and the GaN layer to induce the 2DEG. In some embodiments, a lower aluminum concentration AlₓGaₓ₋₁N layer of about 10% Al (i.e., x≈0.10) is deployed for improved device performance and characteristics. In some embodiments, the lower aluminum concentration AlₓGaₓ₋₁N layer is inserted in the device stack under the high aluminum concentration AlₓGaₓ₋₁N layer, and used as an etch stop layer. For example, the lower aluminum concentration AlₓGaₓ₋₁N layer may act as an etch stop layer under the high aluminum concentration AlₓGaₓ₋₁N layer to reduce etch rate and reliably stop the gate etch on the GaN semiconductor layer. This improves etch reliability both across a wafer and wafer-to-wafer which, in turn, provides reliable Emode (enhancement mode) threshold voltage across devices for improved threshold voltage uniformity. Furthermore, the lower aluminum concentration AlₓGaₓ₋₁N layer reduces alloy scattering (i.e., undesirable scattering at interfaces between binary alloy and ternary alloy semiconductors), which improves electron mobility in the channel.

In addition or in the alternative, the lower aluminum concentration AlxGax-IN layer may be deployed as a gate liner. For example, in a gate structure, the lower aluminum concentration AlₓGaₓ₋₁N layer gate liner may be formed on the channel semiconductor. A gate dielectric layer such as a gate oxide may then be formed on the lower aluminum concentration AlₓGaₓ₋₁N layer and a gate electrode may be formed on the gate dielectric layer. The lower aluminum concentration AlₓGaₓ₋₁N layer gate liner reduces or prevents source to drain leakage through gate corners, which may be present in enhancement mode devices including a gate dielectric layers. Thereby, a lower aluminum concentration AlₓGaₓ₋₁N layer gate liner, when placed under a gate dielectric layer, achieves lower gate leakage current for enhancement mode GaN MOS (metal-oxide-semiconductor) HEMT devices. Furthermore, in either context, as a crystalline layer, the lower aluminum concentration AlₓGaₓ₋₁N layer also preserves the pristine as-grown AlGaN/GaN interface, which then has a lower concentration of traps, achieving better bias temperature stability and, hence, better reliability. These and other advantages will be evident based on the discussed embodiments.

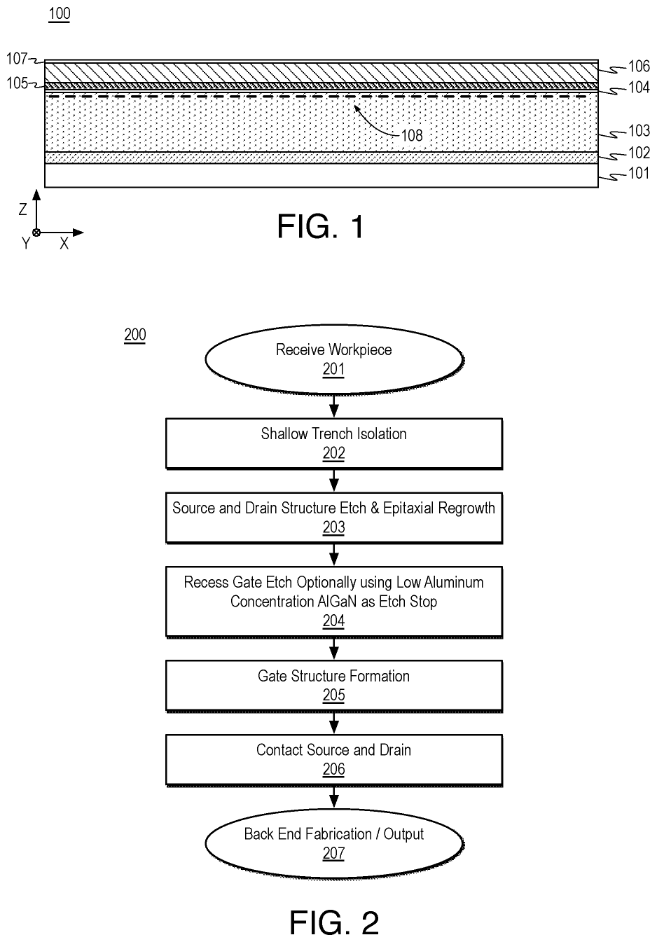

FIG. 1 illustrates a cross-sectional side view of a device material stack 100 for use in a high electron mobility transistor operating in enhancement mode, arranged in accordance with at least some implementations of the present disclosure. For example, a high electron mobility transistor (HEMT) may be formed from device material stack 100 as discussed further herein below. As shown, device material stack 100 may include or be formed on a substrate 101. Device material stack 100 includes an aluminum gallium nitride (AlGaN) buffer layer 102 on substrate 101, a gallium nitride (GaN) semiconductor layer 103 on AlGaN buffer layer 102, an optional aluminum nitride (AIN) interlayer 104 on GaN layer 103, a lower aluminum (Al) concentration AlGaN layer 105 on AIN interlayer 104, a higher Al concentration AlGaN layer 106 on lower Al concentration AlGaN layer 105, and an optional silicon nitride (SiN) layer 107 on higher Al concentration AlGaN layer 106. As shown, a 2DEG 108 is induced near a top surface of GaN layer 103. In some embodiments, 2DEG 108 is largely or entirely induced by higher Al concentration AlGaN layer 106. For example, while not being limited by theory, one or both of lower Al concentration AlGaN layer 105 and AIN interlayer 104 may not have a strong enough polarity or dipole to induce 2DEG 108.

Herein, material layers such as alloys are described according to their constituent parts. However, it is understood that such material layers include each constituent part as described. For example, a GaN layer is a material layer including gallium and nitrogen, an AlGaN layer is a material layer including aluminum, gallium, and nitrogen, an AIN layer is a material layer including aluminum and nitrogen, a SiN layer is a material layer including silicon and nitrogen, and so on. Such constituent listings are not repeated herein for the sake of clarity and brevity.

Substrate 101 may include any suitable material or materials. For example, substrate 101 may be a substrate substantially aligned along a predetermined crystal orientation (e.g., <100>, <111>, <110>, or the like). In some embodiments, substrate 101 is a semiconductor material such as monocrystalline silicon (Si), germanium (Ge), silicon germanium (SiGe), a III-V materials based material (e.g., gallium arsenide (GaAs)), a silicon carbide (SiC), a sapphire (Al₂O₃), or any combination thereof. In some embodiments, substrate 101 is silicon having a <111>crystal orientation. In some embodiments, AlGaN buffer layer 102 and substrate 101 have mismatched lattice structures such as a lattice mismatch of between 15% and 50%. In various embodiments, substrate 101 may include metallization interconnect layers for integrated circuits or electronic devices such as transistors, memories, capacitors, resistors, optoelectronic devices, switches, or any other active or passive electronic devices separated by an electrically insulating layer, for example, an interlayer dielectric, a trench insulation layer, or the like.

AlGaN buffer layer 102, GaN layer 103, AIN interlayer 104, lower Al concentration AlGaN layer 105, higher Al concentration AlGaN layer 106, and SiN layer 107 are formed on and over substrate 101, optionally in a single growth operation or environment. Such materials, and, in particular, AlGaN buffer layer 102, GaN layer 103, AIN interlayer 104, lower Al concentration AlGaN layer 105, and higher Al concentration AlGaN layer 106 are crystalline materials. The term crystalline indicates a material having a highly ordered micro-structure or nano-structure forming a crystal lattice, although slight defects may be evident. In some embodiments, AlGaN buffer layer 102, GaN layer 103, AIN interlayer 104, lower Al concentration AlGaN layer 105, and higher Al concentration AlGaN layer 106 have a wurtzite crystal structure.

In some embodiments, AlGaN buffer layer 102 provides a buffer layer for improved crystal structure as the layers are built up in the +z direction. A transition may then be made to GaN layer 103, which is substantially pure or pure GaN having a high quality or pristine crystal structure moving to a top surface thereof. In some embodiments, AlGaN buffer layer 102 and GaN layer 103 have a thickness on the order of about 1 micron such as a thickness in the range of about 800 to 1,200 nanometers. Herein, a thickness is measured, unless otherwise indicated, with respect to the +z direction. Such thicknesses may be determined using any suitable technique or techniques measuring a single thickness, averaging multiple thicknesses, or the like. In some embodiments, a top thickness of GaN layer 103 of about 50 to 100 nm or more is high quality or pristine crystal pure GaN such that GaN layer 103 may be used as a channel semiconductor for an eventual HEMT device. Although discussed with respect to GaN, layer 103 may be any suitable group III-nitride (III-N) layer. For example, the group III element may be one or more of aluminum, gallium, or indium.

As shown, AIN interlayer 104 is on GaN layer 103. AIN interlayer 104 is pure or substantially pure aluminum nitride and may have any suitable thickness such as a thickness of about 1 nm. In some embodiments, AIN interlayer 104 provides an interface to GaN layer 103 for reduced alloy scattering. For example, alloy scattering is an undesirable scattering at interfaces between binary alloy and ternary alloy semiconductors, which is reduced by proving binary AIN on binary GaN. For example, fabricating ternary lower Al concentration AlGaN layer 105 on AlN interlayer 104 instead of GaN layer 103 reduces undesirable alloy scattering.

Lower Al concentration AlGaN layer 105 is on AIN interlayer 104 and will provide an eventual etch stop and other device advantages as discussed herein. In some embodiments, lower Al concentration AlGaN layer 105 may also be characterized as an interlayer. Lower Al concentration AlGaN layer 105 may have any suitable aluminum concentration such that it is less that of higher Al concentration AlGaN layer 106 to provide an etch selectivity therebetween. In some embodiments, a ratio of an aluminum concentration in higher Al concentration AlGaN layer 106 to an aluminum concentration in lower Al concentration AlGaN layer 105 is not less than four. In some embodiments, the ratio is not less than three. In some embodiments, the ratio is not less than five.

In some embodiments, the aluminum concentration in lower Al concentration AlGaN layer 105 is substantially equal to 10% aluminum (i.e., AlₓGaₓ₋₁N, x≈0.1). In some embodiments, the aluminum concentration in lower Al concentration AlGaN layer 105 is not more than 15% aluminum (i.e., AlₓGaₓ₋₁N, x≤0.15). In some embodiments, the aluminum concentration in lower Al concentration AlGaN layer 105 is not more than 10% aluminum (i.e., AlₓGaₓ₋₁N, x≤0.10). In some embodiments, the aluminum concentration in lower Al concentration AlGaN layer 105 is in the range of 5% to 15% aluminum (i.e., AlₓGaₓ₋₁N, 0.05 ≤x≤ 0.15). In some embodiments, the aluminum concentration in lower Al concentration AlGaN layer 105 is in the range of 8% to 11% aluminum (i.e., AlₓGaₓ₋₁N, 0.08 ≤x≤0.11). In some embodiments, the aluminum concentration in lower Al concentration AlGaN layer 105 is in the range of 8% to 9% aluminum (i.e., AlₓGaₓ₋₁N, 0.08≤x≤0.09). The material composition of lower Al concentration AlGaN layer 105 (or any other material discussed herein) may be determined using any suitable technique or techniques such as sampling a portion of lower Al concentration AlGaN layer 105 and measuring its composition, sampling multiple portions of lower Al concentration AlGaN layer 105, measuring their compositions, and averaging them, and so on. Lower Al concentration AlGaN layer 105 may have any suitable thickness such as a thickness in the range of 2 to 5 nm or a thickness in the range of 3 to 4 nm.

Higher Al concentration AlGaN layer 106 is on lower Al concentration AlGaN layer 105 and induces 2DEG 108 in GaN layer 103. For example, higher Al concentration AlGaN layer 106 may be characterized as a polarization layer. Higher Al concentration AlGaN layer 106 may have any suitable aluminum concentration such that 2DEG 108 is induced in GaN layer 103. In some embodiments, the aluminum concentration in higher Al concentration AlGaN layer 106 is substantially equal to 40% aluminum (i.e., AlₓGaₓ₋₁N, x≈0.4). In some embodiments, the aluminum concentration in higher Al concentration AlGaN layer 106 is not less than 25% aluminum (i.e., AlₓGaₓ₋₁N, x≥0.25). In some embodiments, the aluminum concentration in higher Al concentration AlGaN layer 106 is not less than 40% aluminum (i.e., AlₓGaₓ₋₁N, x≥0.4). In some embodiments, the aluminum concentration in higher Al concentration AlGaN layer 106 is in the range of 25% to 42% aluminum (i.e., AlₓGaₓ₋₁N, 0.25≤x≤0.42). In some embodiments, the aluminum concentration in higher Al concentration AlGaN layer 106 is in the range of 35% to 42% aluminum (i.e., AlₓGaₓ₋₁N, 0.35 ≤ x ≤ 0.42). In some embodiments, the aluminum concentration in higher Al concentration AlGaN layer 106 is in the range of 40% to 42% aluminum (i.e., AlₓGaₓ₋₁N, 0.4≤x≤0.42). Higher Al concentration AlGaN layer 106 may have any suitable thickness such as a thickness in the range of 8 to 12 nm or a thickness of about 10 nm.

SiN layer 107 may be on higher Al concentration AlGaN layer 106, and SiN layer 107 may provide protection during some processing to form an eventual HEMT device. For example, SiN layer 107 may be characterized as a capping layer or a protective layer. SiN layer 107 is pure or substantially pure silicon nitride and may have any suitable thickness such as a thickness in the range of 1 to 2 nm. In subsequent illustrations, SiN layer 107 is not depicted for the sake of clarity of presentation.

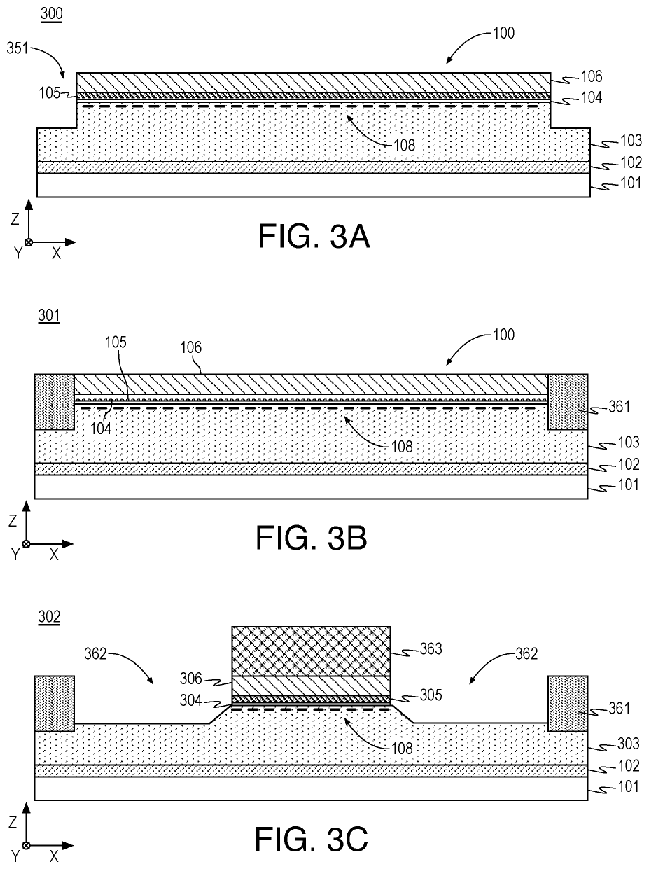

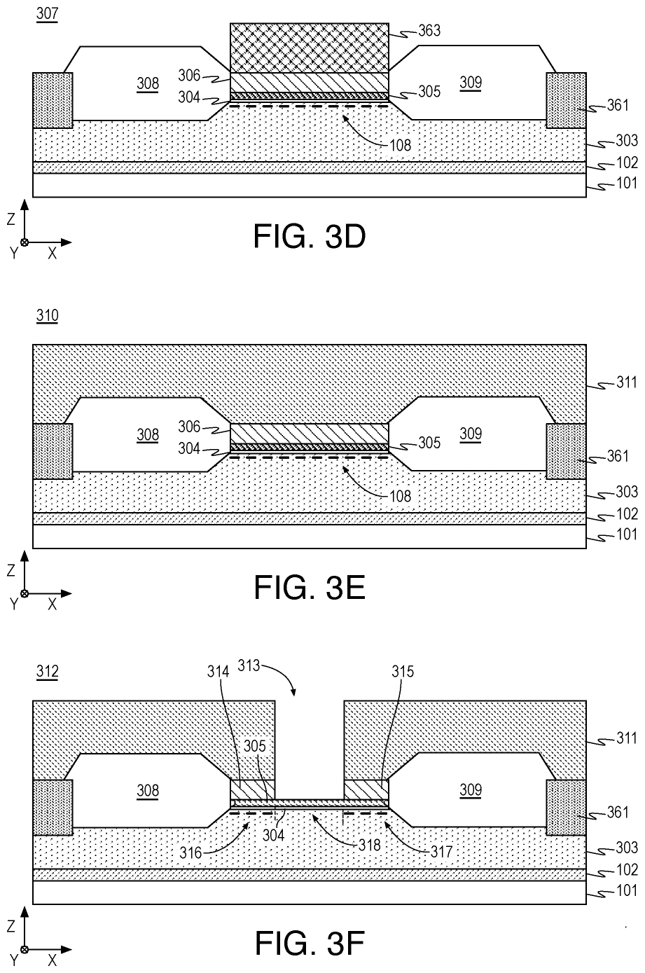

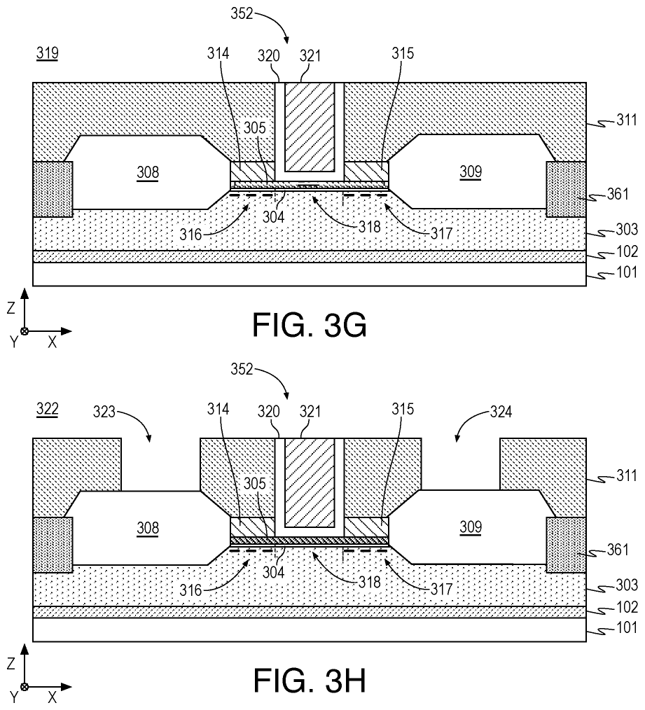

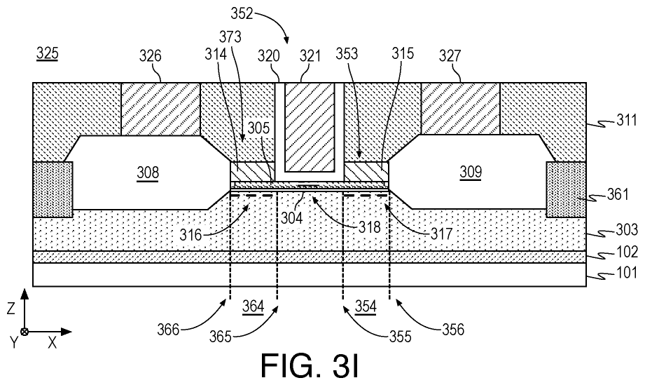

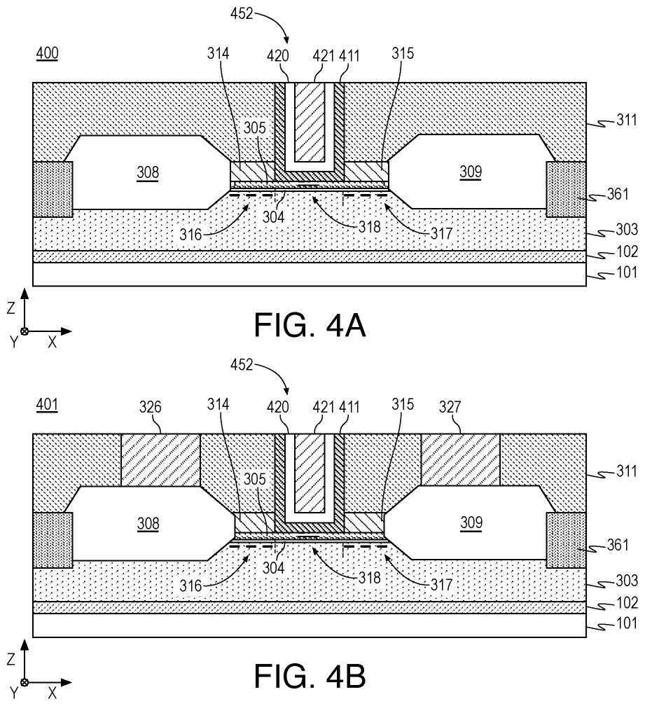

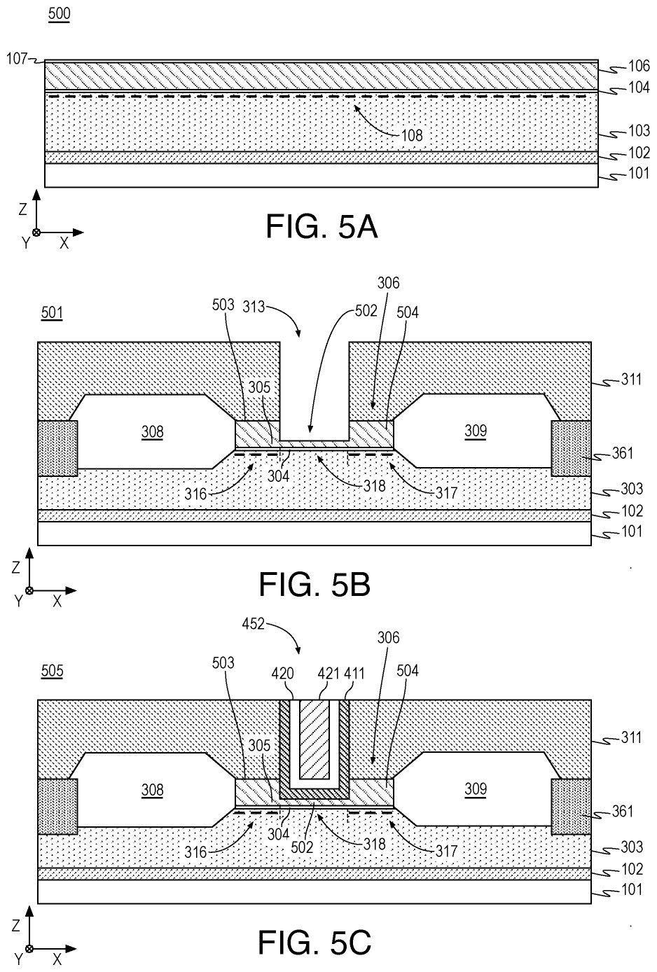

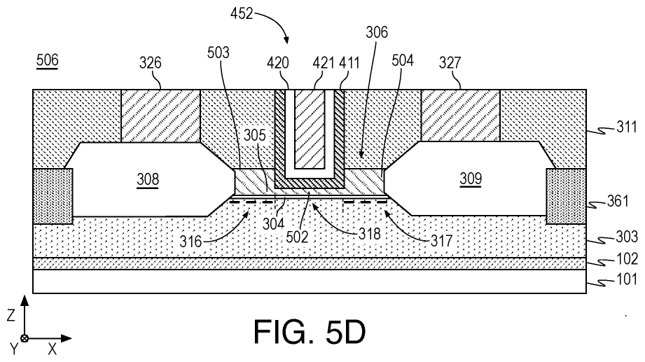

FIG. 2 is a flow diagram illustrating methods 200 for forming a group III-N high electron mobility transistor (HEMT) structure having a low aluminum concentration aluminum gallium nitride layer, arranged in accordance with some embodiments of the disclosure. Methods 200 may be practiced, for example, to fabricate any HEMT structure discussed herein. FIGS. 3A, 3B, 3C, 3D, 3E, 3F, 3G, 3H, and 31 are cross-sectional views of a HEMT structure having a low aluminum concentration aluminum gallium nitride layer between the gate and source and the gate and drain evolving as methods 200 are practiced, arranged in accordance with some embodiments of the disclosure. FIGS. 4A and 4B are cross-sectional views of a HEMT structure having a low aluminum concentration aluminum gallium nitride layer gate liner and a low aluminum concentration aluminum gallium nitride layer between the gate and source and the gate and drain evolving as methods 200 are practiced, arranged in accordance with some embodiments of the disclosure. FIGS. 5A, 5B, 5C, and 5D are cross-sectional views of a HEMT structure having a low aluminum concentration aluminum gallium nitride layer gate liner as methods 200 are practiced, arranged in accordance with some embodiments of the disclosure.

Methods 200 begin at input operation 201, where a workpiece including a device material stack on or over a substrate is received. In some embodiments, the device material stack includes a higher Al concentration AlGaN layer on a lower Al concentration AlGaN layer as discussed with respect to device material stack 100 and elsewhere herein. Such device material stacks advantageously provide a lower Al concentration AlGaN layer between the gate and the source and the gate and the drain of the resultant HEMT. In other embodiments, the device material stack does not include a lower Al concentration AlGaN layer, as discussed with respect to device material stack 500 and elsewhere herein. The device material stack 100 may be formed on or over the substrate using any suitable technique or techniques inclusive of metal organic chemical vapor deposition (MOCVD) processing such as MOCVD processing at a temperature in the range of about 1,000 to 1,100° C. In some embodiments, all layers of the device material stack are formed in the operation (e.g., in the same processing chamber) on or over a substrate such as a crystalline silicon wafer.

Processing continues at operation 202, where shallow trench isolation structures are formed to define islands or regions of material stacks in and on which HEMT structures are to be formed. In some embodiments, lithography and etch operations are performed to define trenches or openings for such isolation. The openings may then be filled with isolation material such as silicon oxide. Processing continues at operation 203, where source and drain structures are formed. In some embodiments, source and drain trenches are etched into the device material stack and the source and drain structures are epitaxially grown out of the trenches.

Processing continues at operations 204 and 205, where a gate structure is formed. In some embodiments, subsequent to source and drain epitaxial growth (or regrowth), a dielectric layer is formed over the existing structures. The dielectric layer may optionally be planarized to provide a planar top surface. A gate opening is then formed at operation 204 such that the opening extends through the dielectric layer and through a portion of or an entirety of the higher Al concentration AlGaN layer. For example, the gate opening may be formed using lithography and etch techniques. In embodiments where a lower Al concentration AlGaN layer etch stop layer is deployed (i.e., as illustrated with respect to device material stack 100), the etch entirely removes the higher Al concentration AlGaN layer within the gate opening and the etch stops selectively on or partially within the thickness of the lower Al concentration AlGaN layer. In embodiments where no lower Al concentration AlGaN layer etch stop layer is used (i.e., as illustrated with respect to device material stack 500), a portion of the thickness of the higher Al concentration AlGaN layer may remain within the gate opening. In such contexts, a timed etch may be used.

Subsequent to etch processing (and after resist removal), the gate structure is formed. In some embodiments, the gate structure includes a gate dielectric layer formed in the gate opening and a gate electrode formed on the gate dielectric layer. In some embodiments, the gate structure further includes a lower Al concentration AlGaN layer gate liner that is first formed in the gate opening. Subsequently a gate dielectric layer is formed on the lower Al concentration AlGaN layer gate liner, and a gate electrode is formed on the gate dielectric layer. Such embodiments may reduce leakage current as discussed herein.

Processing continues at operation 206, where source and drain contacts (and optional gate contacts) are formed. In some embodiments, after gate formation, source and drain contact openings are formed using lithography and etch techniques. The openings are then filled with a contact metal or metal(s) that are in direct contact with the epitaxial source and drain formed at operation 203. In some embodiments, the same operations are used to form gate contacts. In some embodiments, the gate electrodes are formed as T-type electrodes with a larger electrode cross section above a fill portion of the gate electrode, although fill portion only gate electrodes are illustrated herein.

Processing continues at operation 207, where continued processing is performed as is known in the art. Such processing may include forming interconnect features including metallization routings and vias, dicing, packaging, assembly, and so on. The resultant device (e.g., integrated circuit die) may then be implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

FIG. 3A illustrates a high electron mobility transistor (HEMT) structure 300 formed from device material stack 100. As shown in FIG. 3A, device material stack 100 may be patterned to form openings or trenches 351 for device isolation. As discussed with respect to methods 200, device material stack 100 may be fabricated in a single operation using, for example, MOCVD crystalline growth processing. Although not illustrated in FIG. 3A and the following, device material stack 100 may include protective SiN layer 107, which may eventually be removed. In some embodiments, a lithographic mask (not shown) is formed on or over device material stack 100 and an etch process such as a plasma etch process etches through a thickness of higher Al concentration AlGaN layer 106, a thickness of lower Al concentration AlGaN layer 105, a thickness of AIN interlayer 104, and a portion of a thickness of GaN layer 103. Trenches 351 are sufficiently deep to define isolation regions. For example, trenches 351 have a depth in the range of about 50 to 250 nm.

FIG. 3B illustrates a HEMT structure 301 similar to HEMT structure 300 after the formation of isolation structures 361. For example, isolation structures 361may surround islands of device material stack 100 where devices are to be formed. In some embodiments, an isolation dielectric such as silicon oxide is blanket deposited and planarized. In some embodiments, after such planarization processing (e.g., chemical mechanical polishing) isolation structures 361 have an uppermost surface that is substantially coplanar with an uppermost surface of device material stack 100.

FIG. 3C illustrates a HEMT structure 302 similar to HEMT structure 301 after the formation of trenches 362 by patterning portions of higher Al concentration AlGaN layer 106, lower Al concentration AlGaN layer 105, AIN interlayer 104, and a portion of a thickness of GaN layer 103 to form higher Al concentration AlGaN device layer 306, lower Al concentration AlGaN device layer 305, AIN device interlayer 304, GaN device layer 303. Such layers may have any characteristics discussed herein including aluminum concentrations, thicknesses, etc. In some embodiments, a mask 363 is formed and patterned such that mask 363 may withstand high temperature processing. For example, mask 363 may be silicon oxide or silicon nitride. In some embodiments, plasma etch processing then etches unmasked portions of higher Al concentration AlGaN layer 106, lower Al concentration AlGaN layer 105, AIN interlayer 104, and of GaN layer 103 to provide trenches 362. In some embodiments, trenches 362 provide a recess in th3 range of 25 to 150 nm.

FIG. 3D illustrates a HEMT structure 307 similar to HEMT structure 302 after the formation of source structure 308 and drain structure 309 in trenches 362. In some embodiments, source structure 308 and drain structure 309 are epitaxially grown using MOCVD processing such that source structure 308 and drain structure 309 are epitaxial to and substantially crystalline matched to Gan device layer 303. Source structure 308 and drain structure 309 may include any suitable material such as indium gallium nitride (e.g., 1 to 10% indium) or doped indium gallium nitride doped with n-type dopants such as silicon or germanium. In some embodiments, top surfaces of source structure 308 and drain structure 309 are above a top surface of higher Al concentration AlGaN device layer 306.

FIG. 3E illustrates a HEMT structure 310 similar to HEMT structure 307 after the formation of a dielectric layer 311. In some embodiments, mask 363 is removed and dielectric layer 311 is blanket deposited and optionally planarized. In some embodiments, dielectric layer 311 is silicon oxide, silicon nitride, or silicon oxynitride. In embodiments where dielectric layer 311 and mask 363 are the same or substantially the same material, dielectric layer 311 may be formed without removal of mask 363. For example, a dielectric material may be blanket deposited and then planarized without removal of mask 363.

FIG. 3F illustrates a HEMT structure 312 similar to HEMT structure 310 after the formation of a gate opening 313 in dielectric layer 311 and in higher Al concentration AlGaN device layer 306, which is segmented into higher Al concentration AlGaN device layers 314, 315. For example, higher Al concentration AlGaN device layer 314 extends from source structure 308 to gate opening 313 and higher Al concentration AlGaN device layer 315 extends from drain structure 309 to gate opening 313. Such removal of higher Al concentration AlGaN device layer 306 from under gate opening 313 also segments 2DEG 108 into 2DEG 316 and 2DEG 317. Such 2DEGs 316, 317 are induced in GaN device layer 303 on opposite sides of a channel region 318. During operation, an applied gate voltage source structure 308 is coupled to drain structure 309 such that current flows from source structure 308 to drain structure through 2DEG 316, channel region 318, and 2DEG 317.

In some embodiments, a photoresist mask (not shown) is patterned over dielectric layer 311 such that the pattern of the photoresist mask defines a location for gate opening 313. In some embodiments, a plasma etch process is then deployed to form gate opening 313 extending through dielectric layer 311 and higher Al concentration AlGaN device layer 306, but selectively stopping on lower Al concentration AlGaN device layer 305. Notably, the etch processing to form gate opening 313 stops on lower Al concentration AlGaN device layer 305 due to the aluminum concentration difference between higher Al concentration AlGaN device layer 306 and lower Al concentration AlGaN device layer 305, which results in an etch selectivity therebetween. Although illustrated as stopping at a top surface of lower Al concentration AlGaN device layer 305, the selective etch may stop at the top surface or slightly below the top surface depending on etch processing conditions. Gate opening 313 may have any suitable length in the x-dimension (i.e., gate length). In some embodiments, the gate length is in the range of 15 to 2,000 nm. In some embodiments, the gate length is in the range of 30 to 500 nm.

FIG. 3G illustrates a HEMT structure 319 similar to HEMT structure 312 after the formation of a gate structure 352 in gate opening 313, on the exposed top surface of lower Al concentration AlGaN device layer 305, and on sidewalls of higher Al concentration AlGaN device layers 314, 315. In the embodiment of FIG. 3G, gate structure 352 includes a gate dielectric layer 320 on the exposed top surface of lower Al concentration AlGaN device layer 305, and on sidewalls of higher Al concentration AlGaN device layers 314, 315 and a gate electrode 321 on gate dielectric layer 320. In some embodiments, gate structure 352 may be a T-type gate structure as is known in the art.

In some embodiments, a gate dielectric layer is first blanket deposited using atomic layer deposition (ALD) process or physical vapor deposition (PVD). Gate dielectric layer 320 may have a high relative permittivity (i.e., dielectric constant, K). In some high-K gate dielectric embodiments, gate dielectric layer 320 is a metal oxide including oxygen and one or more metals, such as, but not limited to, aluminum, hafnium, zirconium, tantalum or titanium. In some embodiments, gate dielectric layer 320 is silicon oxide. In some embodiments, gate dielectric layer 320 has a thickness between 2nm and 10 nm.

A gate electrode layer may then be blanket deposited on the gate dielectric layer and filling gate opening 313. Gate electrode 321 may be or include a metal such as but not limited to platinum, nickel, molybdenum, tungsten, palladium, gold, alloys thereof, or nitrides such as titanium nitride, tantalum nitride, tungsten silicon nitride, or others. In some embodiments, gate electrode 321 includes a work function metal such as platinum and/or nickel and a gate cap metal such as tungsten. After deposition of the gate dielectric layer and the gate electrode layer, a planarization process is performed to remove the gate dielectric layer and the gate electrode layer from an uppermost surface of dielectric layer 311, leaving gate structure 352. In an embodiment, the planarization process includes a CMP process that forms gate structure 352 having an uppermost surface that is substantially coplanar with the uppermost surface of dielectric layer 311.

FIG. 3H illustrates a HEMT structure 322 similar to HEMT structure 319 after the formation of a source contact opening 323 above source structure 308 and a drain contact opening 324 above drain structure 309. In some embodiments, a photoresist mask (not shown) is patterned over dielectric layer 311 and gate structure 352 such that the pattern of the photoresist mask defines a location for source contact opening 323 and drain contact opening 324. Source contact opening 323 and a drain contact opening 324 may then be formed using etch processing such as a plasma etch process. In some embodiments, openings 323, 324 expose entire upper surfaces of one or bother of source structure 308 and drain structure 309 for increased contact area and reduced the contact resistance.

FIG. 3I illustrates a HEMT structure 325 similar to HEMT structure 322 after the formation of a source contact 326 and a drain contact 327. In some embodiments, one or more layers of contact metal are deposited inside each of openings 323, 324 and on the top surfaces of source structure 308 and drain structure 309. In some embodiments, the one or more layers of contact metal are deposited using a plasma enhanced chemical vapor deposition (PECVD) or ALD. Suitable contact metals include, but are not limited to, titanium, aluminum, nickel, or alloys thereof. In some embodiments, a tungsten capping or fill layer is deposited on the one or more layers of contact metal. After metal deposition, planarization processing removes the one or more layers of contact metal from the uppermost surface of dielectric layer 311.

As shown, HEMT structure 322 includes a group III-nitride (III-N) layer or device layer, such as GaN device layer 303, gate structure 352, source structure 308, and drain structure 309 each coupled to the III-N layer, and a multilayer stack 353 over GaN device layer 303 in a region 354 between an outer edge 355 of gate structure 352 and an inner edge 356 of drain structure 309 such that inner edge 356 is proximal to outer edge 355 of gate structure 352. Similarly, a multilayer stack 373 is over GaN device layer 303 in a region 364 between an outer edge 365 of gate structure 352 and an inner edge 366 of drain structure 309 such that inner edge 366 is proximal to outer edge 365 of gate structure 352. As shown, in some embodiments gate structure 352 is in direct contact with AIN device interlayer 304 and higher Al concentration AlGaN device layers 314, 315, source structure 308 is in direct contact with each layer of multilayer stack 373, and drain structure 309 is in direct contact with each layer of multilayer stack 353.

Multilayer stack 353 includes higher Al concentration AlGaN device layer 315 on lower Al concentration AlGaN device layer 305, such that lower Al concentration AlGaN device layer 305 has a first aluminum concentration and higher Al concentration AlGaN device layer 315 has a second aluminum concentration greater than the first aluminum concentration. Lower Al concentration AlGaN device layer 305 and higher Al concentration AlGaN device layer 315 may have any aluminum concentrations discussed herein. In some embodiments, the first aluminum concentration is not more than 15% aluminum. In some embodiments, the second aluminum concentration is not less than 25% aluminum. In some embodiments, a ratio of the second aluminum concentration to the first aluminum concentration is not less than four. In some embodiments, the first aluminum concentration is not more than 10% aluminum and the second aluminum concentration is not less than 40% aluminum.

As discussed, in some embodiments, multilayer stack 353 may also include AIN device interlayer 304 such that AIN device interlayer 304 is substantially pure aluminum nitride. Multilayer stack 373 includes higher Al concentration AlGaN device layer 314 on lower Al concentration AlGaN device layer 305, and multilayer stack 373 may have any characteristics discussed with respect to multilayer stack 353. As shown, in some embodiments, lower Al concentration AlGaN device layer 305 extends from inner edge 356 of drain structure 309, under gate structure 352, to inner edge 366 source structure 308. For example, Al concentration AlGaN device layer 305 may be in direct contact with source structure 308 and drain structure 309, and may be a continuous layer (having a substantially constant thickness) under gate structure 352. Furthermore, higher Al concentration AlGaN is absent under gate structure 352.

Discussion now turns to deployment of a lower Al concentration AlGaN device layer as a gate liner. The lower Al concentration AlGaN layer gate liner may have any characteristics discussed with respect to lower Al concentration AlGaN layers 105, 305, or elsewhere herein. The lower Al concentration AlGaN layer gate liner may be deployed with lower Al concentration AlGaN device layer 305 (as shown with respect to FIGS. 4A and 4B) or without (as shown with respect to FIGS. 5A-5D). In either case, the lower Al concentration AlGaN layer gate liner reduces undesirable gate leakage.

FIG. 4A illustrates a HEMT structure 400 similar to HEMT structure 312 of FIG. 3F after the formation of a gate structure 452 in gate opening 313, on the exposed top surface of lower Al concentration AlGaN device layer 305, and on sidewalls of higher Al concentration AlGaN device layers 314, 315. For example, formation of HEMT structure 400 may include operations up to and including those discussed with respect to FIGS. 3A-3F.

In the embodiment of FIG. 4A, gate structure 452 includes a lower Al concentration AlGaN gate layer 411 on the exposed top surface of lower Al concentration AlGaN device layer 305, and on sidewalls of higher Al concentration AlGaN device layers 314, 315. Lower Al concentration AlGaN gate layer 411 may have any suitable aluminum concentration such that it is less that of higher Al concentration AlGaN device layers 314, 315. In some embodiments, a ratio of an aluminum concentration in higher Al concentration AlGaN device layers 314, 315 to an aluminum concentration in Al concentration AlGaN gate layer 411 is not less than three, four, or five with a ratio of not less than four being particularly advantageous.

In some embodiments, the aluminum concentration in lower Al concentration AlGaN gate layer 411 is substantially equal to 10% aluminum (i.e., AlₓGaₓ₋₁N, x≈0.1). In some embodiments, the aluminum concentration is not more than 15% aluminum (i.e., AlₓGaₓ₋₁N, x≤0.15) or not more than 10% aluminum (i.e., AlₓGaₓ₋₁N, x ≤0.10). In some embodiments, the aluminum concentration in lower Al concentration AlGaN gate layer 411 is in the range of 5% to 15% aluminum (i.e., AlₓGaₓ₋₁N, 0.05 ≤ x≤0.15), in the range of 8% to 11% aluminum (i.e., AlₓGaₓ₋₁N, 0.08≤x≤0.11), or in the range of 8% to 9% aluminum (i.e., AlₓGaₓ₋₁N, 0.08≤x≤0.09). Lower Al concentration AlGaN gate layer 411 may have any suitable thickness such as a thickness in the range of 2 to 5 nm or in the range of 3 to 4 nm. Gate dielectric layer 420 may have any characteristics discussed with respect to gate dielectric layer 320. Similarly, gate electrode 421 may have any characteristics discussed with respect to gate electrode 321.

In some embodiments, a lower Al concentration AlGaN gate layer is first blanket deposited using MOCVD techniques, a gate dielectric layer is then blanket deposited using ALD or PVD, and a gate electrode layer may be blanket deposited on the gate dielectric layer and filling gate opening 313. After deposition of the lower Al concentration AlGaN gate layer, the gate dielectric layer, and the gate electrode layer, a planarization process is performed to remove them an uppermost surface of dielectric layer 311, leaving gate structure 452.

FIG. 4B illustrates a HEMT structure 401 similar to HEMT structure 400 after the formation of source contact 326 and drain contact 327. Source contact 326 and drain contact 327 may be formed using any suitable technique or techniques such as those discussed with respect to FIGS. 3H and 31, and source contact 326 and drain contact 327 may have any characteristics discussed herein. As shown, HEMT structure 401 includes a group III-nitride (III-N) layer or device layer, such as GaN device layer 303, gate structure 452, source structure 308, and drain structure 309 each coupled to the III-N layer, and multilayer stack 353 over GaN device layer 303. HEMT structure 401 may have any characteristics discussed with respect to HEMT structure 325 with the exception that gate structure 452 includes lower Al concentration AlGaN gate layer 411 adjacent to GaN device layer 303 such that lower Al concentration AlGaN gate layer 411 has an aluminum concentration less than the aluminum concentration of AlGaN device layers 314, 315, gate dielectric layer 420 on lower Al concentration AlGaN gate layer 411, and gate electrode 421on gate dielectric layer 420.

Discussion now turns to deployment of a lower Al concentration AlGaN device layer as a gate liner such that the HEMT structure is absent lower Al concentration AlGaN device layer 305 deployed as an etch stop layer.

FIG. 5A illustrates a cross-sectional side view of a device material stack 500 similar to device material stack 100 (refer to FIG. 1) without lower Al concentration AlGaN layer 105. As shown, device material stack 500 AlGaN buffer layer 102 on substrate 101, GaN semiconductor layer 103 on AlGaN buffer layer 102, AIN interlayer 104 on GaN layer 103, higher Al concentration AlGaN layer 106 on AIN interlayer 104, and optional SiN layer 107 on higher Al concentration AlGaN layer 106. Substrate 101 and such layers 102, 103, 104, 106, 107 may have any characteristics discussed herein.

FIG. 5B illustrates a HEMT structure 501 formed from device material stack 500. Notably, HEMT structure 501 is similar to that of HET structure 312 (refer to FIG. 3F) lower Al concentration AlGaN device layer 305. For example, HEMT structure 501 may be formed using the processing techniques discussed with respect to FIGS. 3A-3F. HEMT structure 501 is illustrated after the formation of a gate opening 313 in dielectric layer 311 and in a portion of higher Al concentration AlGaN device layer 306, which is at least partially recessed to form a thin channel region 502 and thick polarization regions 503, 504 that are in contact with source structure 308 and drain structure 309, respectively. In the context of HEMT structure 501 a timed etch may be performed to recess higher Al concentration AlGaN device layer 306.

FIG. 5C illustrates a HEMT structure 505 similar to HEMT structure 501 after the formation of a gate structure 452 in gate opening 313, on the exposed surface of higher Al concentration AlGaN device layer 306 (e.g., on a top surface of thin channel region 502 and sidewall surfaces of thick polarization regions 503, 504). Gate structure 452 includes lower Al concentration AlGaN gate layer 411, gate dielectric layer 420, and gate electrode 421, which may have any characteristics discussed herein such as with respect to HEMT structure 400 (refer to FIG. 4A).

FIG. 5D illustrates a HEMT structure 506 similar to HEMT structure 505 after the formation of source contact 326 and drain contact 327. Source contact 326 and drain contact 327 may be formed using any suitable technique or techniques such as those discussed with respect to

FIGS. 3H and 31, and source contact 326 and drain contact 327 may have any characteristics discussed herein.

As shown, HEMT structure 506 includes a group III-nitride (III-N) layer or device layer, such as GaN device layer 303, gate structure 452, source structure 308, and drain structure 309 each coupled to the III-N layer, and higher Al concentration AlGaN device layer 306 over at least a portion of GaN device layer 303 between gate structure 452 and drain structure 309 and over at least a portion of GaN device layer 303 between gate structure 452 and source structure 308. Higher Al concentration AlGaN device layer 306 has a first aluminum concentration, and gate structure 452 includes lower Al concentration AlGaN gate layer 411 adjacent to GaN device layer 303 such that lower Al concentration AlGaN gate layer 411 has a second aluminum concentration less than the first aluminum concentration. Gate structure 452 further includes gate dielectric layer 420 on lower Al concentration AlGaN gate layer 411, and gate electrode 421 on gate dielectric layer 420. In some embodiments, the second aluminum concentration is not more than 15% aluminum. In some embodiments, the first aluminum concentration is not less than 25% aluminum. In some embodiments, a ratio of the first aluminum concentration to the second aluminum concentration is not less than four. In some embodiments, the second aluminum concentration is not more than 10% aluminum and the first aluminum concentration is not less than 40% aluminum. In some embodiments,

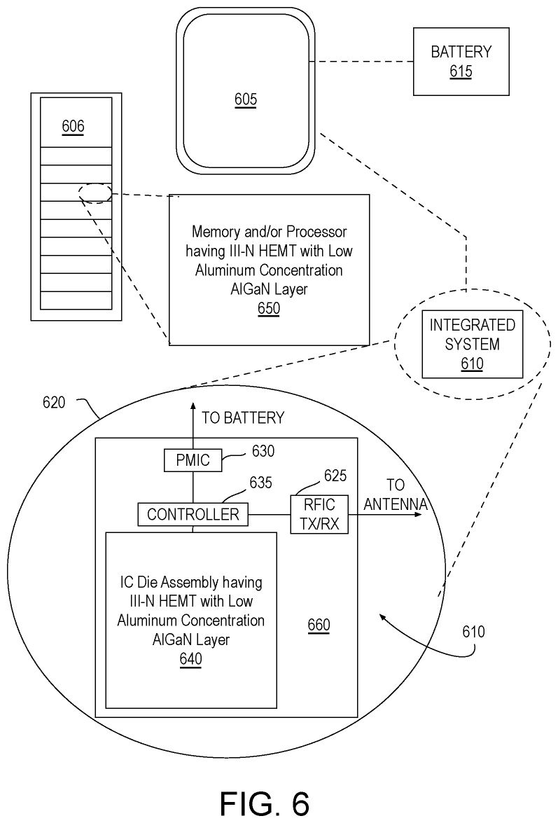

FIG. 6 illustrates exemplary systems employing a HEMT with a low aluminum concentration aluminum gallium nitride interlayer, in accordance with some embodiments. The system may be a mobile computing platform 605 and/or a data server machine 606, for example. Either may employ a monolithic IC die, for example, having a field effect transistor having a low aluminum concentration aluminum gallium nitride interlayer as described elsewhere herein. Server machine 606 may be any commercial server, for example including any number of high-performance computing platforms disposed within a rack and networked together for electronic data processing, which in the exemplary embodiment includes an IC die assembly 650 with a field effect transistor having a low aluminum concentration aluminum gallium nitride interlayer as described elsewhere herein. Mobile computing platform 605 may be any portable device configured for each of electronic data display, electronic data processing, wireless electronic data transmission, or the like. For example, mobile computing platform 605 may be any of a tablet, a smart phone, a laptop computer, etc., and may include a display screen (e.g., a capacitive, inductive, resistive, or optical touchscreen), a chip-level or package-level integrated system 610, and a battery 615. Although illustrated with respect to mobile computing platform 605, in other examples, chip-level or package-level integrated system 610 and a battery 615 may be implemented in a desktop computing platform, an automotive computing platform, an internet of things platform, or the like. As discussed below, in some examples, the disclosed systems may include a sub-system 660 such as a system on a chip (SOC) or an integrated system of multiple ICs, which is illustrated with respect to mobile computing platform 605.

Whether disposed within integrated system 610 illustrated in expanded view 620 or as a stand-alone packaged device within data server machine 606, sub-system 660 may include memory circuitry and/or processor circuitry 640 (e.g., RAM, a microprocessor, a multi-core microprocessor, graphics processor, etc.), a power management integrated circuit (PMIC) 630, a controller 635, and a radio frequency integrated circuit (RFIC) 625 (e.g., including a wideband RF transmitter and/or receiver (TX/RX)). As shown, one or more IC dice, such as memory circuitry and/or processor circuitry 640 may be assembled and implemented such that one or more have a field effect transistor with a low aluminum concentration aluminum gallium nitride interlayer as described herein. In some embodiments, RFIC 625 includes a digital baseband and an analog front end module further comprising a power amplifier on a transmit path and a low noise amplifier on a receive path). Functionally, PMIC 630 may perform battery power regulation, DC-to-DC conversion, etc., and so has an input coupled to battery 615, and an output providing a current supply to other functional modules. As further illustrated in FIG. 6, in the exemplary embodiment, RFIC 625 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 640 may provide memory functionality for sub-system 660, high level control, data processing and the like for sub-system 660. In alternative implementations, each of the SOC modules may be integrated onto separate ICs coupled to a package substrate, interposer, or board.

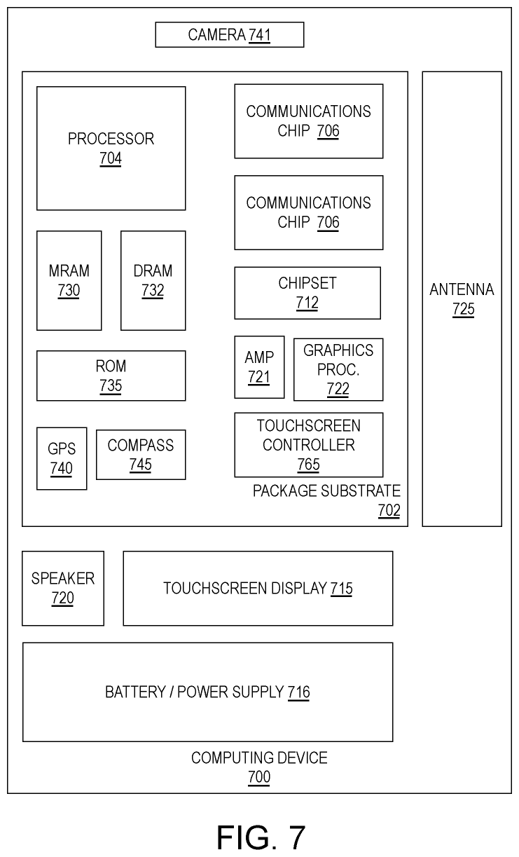

FIG. 7 is a functional block diagram of an electronic computing device 700, in accordance with some embodiments. For example, device 700 may, via any suitable component therein, implement a field effect transistor with a low aluminum concentration aluminum gallium nitride interlayer as discussed herein. For example, one or more IC dies of electronic computing device 700 may deploy a field effect transistor with a low aluminum concentration aluminum gallium nitride interlayer. Device 700 further includes a motherboard or package substrate 702 hosting a number of components, such as, but not limited to, a processor 704 (e.g., an applications processor). Processor 704 may be physically and/or electrically coupled to package substrate 702. In some examples, processor 704 is within an IC assembly. In general, the term “processor” or “microprocessor” may refer to any device or portion of a device that processes electronic data from registers and/or memory to transform that electronic data into other electronic data that may be further stored in registers and/or memory.

In various examples, one or more communication chips 706 may also be physically and/or electrically coupled to the package substrate 702. In further implementations, communication chips 706 may be part of processor 704. Depending on its applications, computing device 700 may include other components that may or may not be physically and electrically coupled to package substrate 702. These other components include, but are not limited to, volatile memory (e.g., DRAM 732), non-volatile memory (e.g., ROM 735), flash memory (e.g., NAND or NOR), magnetic memory (MRAM 730), a graphics processor 722, a digital signal processor, a crypto processor, a chipset 712, an antenna 725, touchscreen display 715, touchscreen controller 765, battery/power supply 716, audio codec, video codec, power amplifier 721, global positioning system (GPS) device 740, compass 745, accelerometer, gyroscope, speaker 720, camera 741, and mass storage device (such as hard disk drive, solid-state drive (SSD), compact disk (CD), digital versatile disk (DVD), and so forth, or the like.

Communication chips 706 may enable wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 706 may implement any of a number of wireless standards or protocols, including, but not limited to, those described elsewhere herein. As discussed, computing device 700 may include a plurality of communication chips 706. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others. Battery/power supply 716 may include any suitable power supply circuitry and, optionally, a battery source to provide power to components of electronic computing device 700.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertains to exemplary embodiments.

In one or more first embodiments, a transistor structure comprises a group III-nitride (III-N) layer, a gate structure, a source structure, and a drain structure coupled to the III-N layer, and a multilayer stack over the III-N layer in a region between an outer edge of the gate structure and an edge of the drain structure proximal to the outer edge of the gate structure, the multilayer stack comprising a first aluminum gallium nitride layer having a first aluminum concentration and a second aluminum gallium nitride layer on the first gallium nitride layer, the second aluminum gallium nitride layer having second aluminum concentration greater than the first aluminum concentration.

In one or more second embodiments, further to the first embodiments, the first aluminum concentration is not more than 15% aluminum.

In one or more third embodiments, further to the first or second embodiments, the second aluminum concentration is not less than 25% aluminum.

In one or more fourth embodiments, further to the first through third embodiments, a ratio of the second aluminum concentration to the first aluminum concentration is not less than four.

In one or more fifth embodiments, further to the first through fourth embodiments, the first aluminum concentration is not more than 10% aluminum and the second aluminum concentration is not less than 40% aluminum.

In one or more sixth embodiments, further to the first through fifth embodiments, the gate structure comprises a third aluminum gallium nitride layer adjacent to the III-N layer, the third aluminum gallium nitride layer having third aluminum concentration less than the second aluminum concentration, a gate dielectric layer on the third aluminum gallium nitride layer, and a gate electrode on the gate dielectric layer.

In one or more seventh embodiments, further to the first through sixth embodiments, the third aluminum concentration is not more than 15% aluminum.

In one or more eighth embodiments, further to the first through seventh embodiments, the multilayer stack further comprises a third layer comprising substantially pure aluminum nitride, wherein the first aluminum gallium nitride layer is on the third layer and the third layer is on the III-N layer.

In one or more ninth embodiments, further to the first through eighth embodiments, the first aluminum gallium nitride layer extends from the edge of the drain structure, under the gate structure, to an edge of the source structure proximal to the gate structure.

In one or more tenth embodiments, further to the first through ninth embodiments, the second aluminum gallium nitride layer is absent under the gate structure.

In one or more eleventh embodiments, further to the first through tenth embodiments, the first aluminum gallium nitride layer has a thickness in the range of 2 to 5 nm and the second aluminum gallium nitride layer has a thickness in the range of 7 to 13 nm.

In one or more twelfth embodiments, further to the first through eleventh embodiments, the III-N layer comprises substantially pure gallium nitride, and the source and drain structures are epitaxial to the III-N layer.

In one or more thirteenth embodiments, a transistor structure comprises a group III-nitride (III-N) layer, a gate structure, a source structure, and a drain structure coupled to the III-N layer, and first aluminum gallium nitride layer over at least a portion of the III-N layer between the gate structure and the drain structure, the first aluminum gallium nitride layer having a first aluminum concentration, wherein the gate structure comprises a second aluminum gallium nitride layer adjacent to the III-N layer, the second aluminum gallium nitride layer having a second aluminum concentration less than the first aluminum concentration, a gate dielectric layer on the third aluminum gallium nitride layer, and a gate electrode on the gate dielectric layer.

In one or more fourteenth embodiments, further to the thirteenth embodiments, the second aluminum concentration is not more than 15% aluminum.

In one or more fifteenth embodiments, further to the thirteenth or fourteenth embodiments, the first aluminum concentration is not less than 25% aluminum.

In one or more sixteenth embodiments, further to the thirteenth through fifteenth embodiments, a ratio of the first aluminum concentration to the second aluminum concentration is not less than four.

In one or more seventeenth embodiments, further to the thirteenth through sixteenth embodiments, the second aluminum concentration is not more than 10% aluminum and the first aluminum concentration is not less than 40% aluminum.

In one or more eighteenth embodiments, further to the thirteenth through seventeenth embodiments, the III-N layer comprises substantially pure gallium nitride, and the source and drain structures are epitaxial to the III-N layer.

In one or more nineteenth embodiments, a system comprises an integrated circuit (IC) die having a transistor structure according to any of the apparatuses of the first through eighteenth embodiments, and a power supply coupled to the IC die.

In one or more twentieth embodiments, a system comprises an integrated circuit (IC) die comprising a transistor structure, the transistor structure comprising a group III-nitride (III-N) layer, a gate structure, a source structure, and a drain structure coupled to the III-N layer, a first aluminum gallium nitride layer over at least a portion of the III-N layer between the gate structure and the drain structure, the first aluminum gallium nitride layer having a first aluminum concentration, and a second aluminum gallium nitride layer on the first aluminum gallium nitride layer, the second aluminum gallium nitride layer having a second aluminum concentration less than the first aluminum concentration, and a power supply coupled to the IC die.

In one or more twenty-first embodiments, further to the twentieth embodiments, a ratio of the first aluminum concentration to the second aluminum concentration is not less than four.

In one or more twenty-second embodiments, further to the twentieth or twenty-first embodiments, the transistor structure comprises a multilayer stack over the III-N layer in a region between an outer edge of the gate structure and an edge of the drain structure proximal to the outer edge of the gate structure, the multilayer stack comprising the first and second gallium nitride layers.

In one or more twenty-third embodiments, further to the twentieth through twenty-second embodiments, the gate structure comprises the second aluminum gallium nitride layer, a gate dielectric layer on the third aluminum gallium nitride layer, and a gate electrode on the gate dielectric layer.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. A transistor structure, comprising:
a group III-nitride (III-N) layer;
a gate structure, a source structure, and a drain structure coupled to the III-N layer; and
a multilayer stack over the III-N layer in a region between an outer edge of the gate structure and an edge of the drain structure proximal to the outer edge of the gate structure, the multilayer stack comprising:
a first aluminum gallium nitride layer having a first aluminum concentration; and
a second aluminum gallium nitride layer on the first gallium nitride layer, the second aluminum gallium nitride layer having second aluminum concentration greater than the first aluminum concentration.

2. The transistor structure of claim 1, wherein the first aluminum concentration is not more than 15% aluminum.

3. The transistor structure of claim 2, wherein the second aluminum concentration is not less than 25% aluminum.

4. The transistor structure of claim 1, wherein a ratio of the second aluminum concentration to the first aluminum concentration is not less than four.

5. The transistor structure of claim 1, wherein the first aluminum concentration is not more than 10% aluminum and the second aluminum concentration is not less than 40% aluminum.

6. The transistor structure of claim 1, wherein the gate structure comprises:
a third aluminum gallium nitride layer adjacent to the III-N layer, the third aluminum gallium nitride layer having third aluminum concentration less than the second aluminum concentration;
a gate dielectric layer on the third aluminum gallium nitride layer; and
a gate electrode on the gate dielectric layer.

7. The transistor structure of claim 6, wherein the third aluminum concentration is not more than 15% aluminum.

8. The transistor structure of claim 1, wherein the multilayer stack further comprises a third layer comprising substantially pure aluminum nitride, wherein the first aluminum gallium nitride layer is on the third layer and the third layer is on the III-N layer.

9. The transistor structure of claim 1, wherein the first aluminum gallium nitride layer extends from the edge of the drain structure, under the gate structure, to an edge of the source structure proximal to the gate structure.

10. The transistor structure of claim 9, wherein the second aluminum gallium nitride layer is absent under the gate structure.

11. The transistor structure of claim 1, wherein the first aluminum gallium nitride layer has a thickness in the range of 2 to 5 nm and the second aluminum gallium nitride layer has a thickness in the range of 7 to 13 nm.

12. The transistor structure of claim 1, wherein the III-N layer comprises substantially pure gallium nitride, and the source and drain structures are epitaxial to the III-N layer.

13. A transistor structure, comprising:
a group III-nitride (III-N) layer;
a gate structure, a source structure, and a drain structure coupled to the III-N layer; and
a first aluminum gallium nitride layer over at least a portion of the III-N layer between the gate structure and the drain structure, the first aluminum gallium nitride layer having a first aluminum concentration, wherein the gate structure comprises:
a second aluminum gallium nitride layer adjacent to the III-N layer, the second aluminum gallium nitride layer having a second aluminum concentration less than the first aluminum concentration;
a gate dielectric layer on the third aluminum gallium nitride layer; and
a gate electrode on the gate dielectric layer.

14. The transistor structure of claim 13, wherein the second aluminum concentration is not more than 15% aluminum.

15. The transistor structure of claim 14, wherein the first aluminum concentration is not less than 25% aluminum.

16. The transistor structure of claim 13, wherein a ratio of the first aluminum concentration to the second aluminum concentration is not less than four.

17. The transistor structure of claim 13, wherein the second aluminum concentration is not more than 10% aluminum and the first aluminum concentration is not less than 40% aluminum.

18. The transistor structure of claim 13, wherein the III-N layer comprises substantially pure gallium nitride, and the source and drain structures are epitaxial to the III-N layer.

19. A system, comprising:
an integrated circuit (IC) die comprising a transistor structure, the transistor structure comprising:
a group III-nitride (III-N) layer;
a gate structure, a source structure, and a drain structure coupled to the III-N layer;
a first aluminum gallium nitride layer over at least a portion of the III-N layer between the gate structure and the drain structure, the first aluminum gallium nitride layer having a first aluminum concentration; and
a second aluminum gallium nitride layer on the first aluminum gallium nitride layer, the second aluminum gallium nitride layer having a second aluminum concentration less than the first aluminum concentration; and
a power supply coupled to the IC die.

20. The system of claim 19, wherein a ratio of the first aluminum concentration to the second aluminum concentration is not less than four.

21. The system of claim 19, wherein the transistor structure comprises a multilayer stack over the III-N layer in a region between an outer edge of the gate structure and an edge of the drain structure proximal to the outer edge of the gate structure, the multilayer stack comprising the first and second gallium nitride layers.

22. The system of claim 19, wherein the gate structure comprises the second aluminum gallium nitride layer, a gate dielectric layer on the third aluminum gallium nitride layer, and a gate electrode on the gate dielectric layer.
